(19) United States
(12) Patent Application Publication
(10) Pub. No.: US 2026/0031174 A1
(43) Pub. Date: Jan. 29, 2026

(54) CONFIDENCE ADJUSTMENT FOR READ ERROR HANDLING USING STROBE INFORMATION

(71) Applicant: MICRON TECHNOLOGY, INC., Boise, ID (US)

(72) Inventors: Sundararajan Sankaranarayanan, Fremont, CA (US); Jeffrey S. McNeil, Nampa, ID (US)

(21) Appl. No.: 19/280,362

(22) Filed: Jul. 25, 2025

Related U.S. Application Data
(60) Provisional application No. 63/675,947, filed on Jul. 26, 2024.

(51) Int. Cl. G11C 29/44; G11C 29/42

(52) U.S. Cl. CPC G11C 29/44; G11C 29/42

(57) ABSTRACT

A system includes a memory device; and a processing device, operatively coupled with the memory device, to perform operations including performing, on encoded host data stored in the memory device, a read operation comprising a sequence of strobes; obtaining first data from applying the sequence of strobes; obtaining second data from applying a last strobe of the sequence of strobes, the last strobe being performed most recently among the sequence of strobes; identifying, based on the first data and the second data, one or more faulty bits of the first data; obtaining, for each faulty bit of the one or more faulty bits of the first data, a respective likelihood value reflecting a probability of the bit be decoded as a specific binary value; and decoding, using the likelihood values, the encoded host data to produce decoded data.

### RELATED APPLICATIONS

This application claims the benefit of U.S. Provisional Patent Application No. 63/675,947, filed Jul. 26, 2024, the entire contents of which are incorporated by reference herein.

### TECHNICAL FIELD

Embodiments of the disclosure relate generally to memory sub-systems, and more specifically, relate to adjusting confidence for read error handling using strobe information.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system in accordance with some embodiments of the present disclosure.

FIG. 1B is a block diagram of memory device(s) in communication with a memory sub-system controller of a memory sub-system, in accordance with some embodiments of the present disclosure.

FIG. 2 is a diagram of a portion of a memory device in accordance with some embodiments of the present disclosure.

FIG. 3 illustrates schematically an example of a distribution of threshold control gate voltages for a memory cell in a memory device, in accordance with some embodiments of the present disclosure.

FIG. 4 is a flow diagram of an example method to adjust confidence for read error handling using strobe information in a memory device, in accordance with some embodiments of the present disclosure.

FIG. 5 illustrates an example of adjusting confidence for read error handling using strobe information, in accordance with some embodiments of the present disclosure.

FIG. 6 illustrates an example of a data structure storing likelihood values corresponding to a logical level for use during read error handling, in accordance with some embodiments of the present disclosure.

FIG. 7 is a block diagram of an example computer system in which embodiments of the present disclosure may operate.

### DETAILED DESCRIPTION

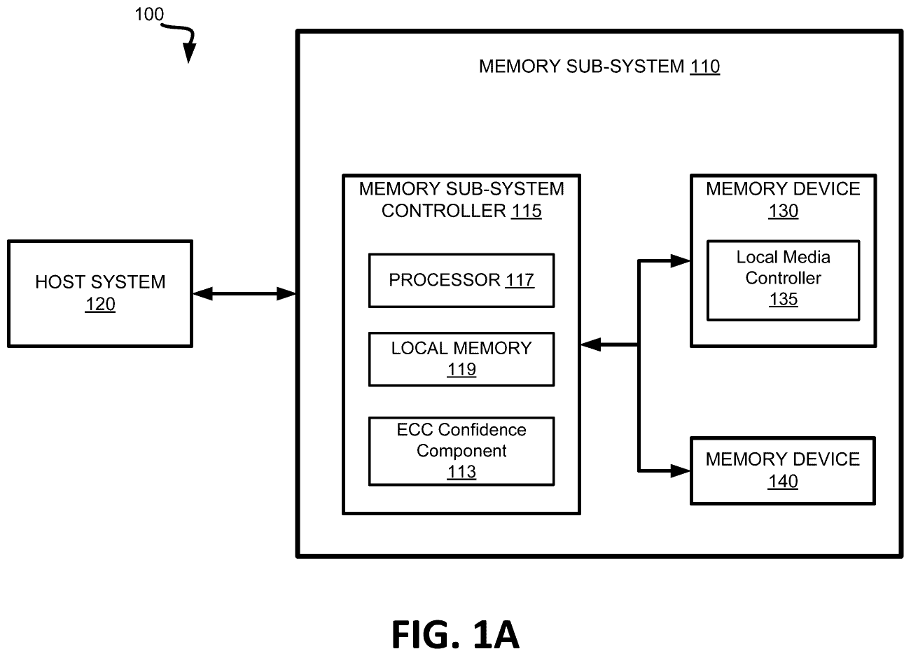

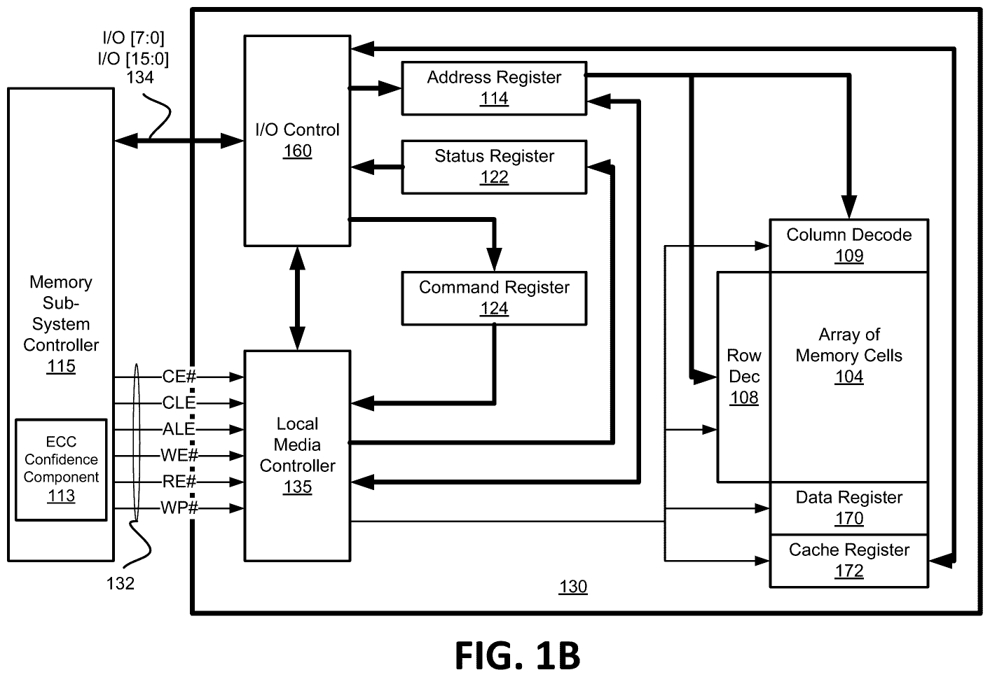

Aspects of the present disclosure are directed to adjust confidence for read error handling using strobe information in a memory device. A memory sub-system can be a storage device, a memory module, or a combination of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIG. 1A. A non-volatile memory device is a package of one or more dies. Each die includes one or more planes. For some types of non-volatile memory devices (e.g., NAND devices), each plane includes a set of physical blocks. Each block consists of a set of pages. Each page includes a set of memory cells. A memory cell is an electronic circuit that stores information. Depending on the memory cell type, a memory cell can store one or more bits of binary information, and has various logic states that correlate to the number of bits being stored. The logic states can be represented by binary values, such as “0” and “1”, or combinations of such values.

A memory device may include multiple memory cells arranged in a two-dimensional grid. The memory cells are formed onto a silicon wafer in an array of columns and rows. A memory cell includes a capacitor that holds an electric charge and a transistor that acts as a switch controlling access to the capacitor. Accordingly, the memory cell may be programmed (written to) by applying a certain voltage, which results in an electric charge being held by the capacitor. The memory cells are joined by wordlines, which are conducting lines electrically connected to the control gates of the memory cells, and bitlines, which are conducting lines electrically connected to the drain electrodes of the memory cells.

Depending on the cell type, each memory cell may store one or more bits of binary information and has various logic states that correlate to the number of bits being stored. The logic states may be represented by binary values, such as “0” and “1”, or combinations of such values. Memory access operations (e.g., a read operation, a programming (write) operation, an erase operation, etc.) may be executed with respect to sets of the memory cells, e.g., in response to receiving memory access commands from the host. A memory access operation may specify the requested memory access operation (e.g., write, erase, read, etc.) and a logical address, which the memory sub-system would translate to a physical address identifying a set of memory cells (e.g., a block).

A memory cell may be programmed (written to) by applying a certain voltage to the memory cell, which results in an electric charge being held by the memory cell. For example, a voltage signal V_{CG} that can be applied to a control electrode of the cell to open the cell to the flow of electric current across the cell, between a source electrode and a drain electrode. More specifically, for each individual cell (having a charge Q stored thereon) there can be a threshold control gate voltage V_{T} (also referred to as the “threshold voltage”) such that the source-drain electric current is low for the control gate voltage (V_{CG}) being below the threshold voltage, V_{CG}<V_{T}. The current increases substantially once the control gate voltage has exceeded the threshold voltage, V_{CG}>V_{T}. Because the actual geometry of the electrodes and gates varies from cell to cell, the threshold voltages can be different even for cells implemented on the same die. The cells can, therefore, be characterized by a distribution P of the threshold voltages, P(Q,V_{T})=dW/dV_{T}, where dW represents the probability that any given cell has its threshold voltage within the interval [V_{T},V_{T}+dV_{T}] when charge Q is placed on the cell.

A memory device can exhibit threshold voltage distributions P(Q,V_{T}) that are narrow compared with the working range of control voltages tolerated by the cells of the device. Accordingly, multiple non-overlapping distributions P(Qₖ,V_{T}) (“valleys”) can be fit into the working range allowing for storage and reliable detection of multiple values of the charge Qₖ, k=1, 2, 3 . . . . The distributions (valleys) are interspersed with voltage intervals (“valley margins”) where none (or very few) of the cells of the device have their threshold voltages. Such valley margins can, therefore, be used to separate various charge states Qₖ—the logical state of the cell can be determined by detecting, during a read operation, between which two valley margins the respective threshold voltage V_{T} of the cell resides. Specifically, the read operation can be performed by comparing the measured threshold voltage V_{T} exhibited by the memory cell to one or more reference voltage levels corresponding to known valley margins (e.g., centers of the margins) of the memory device. Each logical state may be translated into a corresponding binary representation of the content of the memory cell. In an illustrative example, a gray code may be employed for translating the cell charge levels (voltage levels) into their respective binary representations and vice versa. A gray code refers to an encoding in which adjacent numbers have a single digit different by one.

One type of cell is a single level cell (SLC), which stores 1 bit per cell and defines 2 logical states (“states”) (“1” or “L0” and “0” or “L1”) each corresponding to a respective V_{T} level. For example, the “1” state can be an erased state and the “0” state can be a programmed state (L1). Another type of cell is a multi-level cell (MLC), which stores 2 bits per cell and defines 4 states (“11” or “L0”, “10” or “L1”, “01” or “L2” and “00” or “L3”) each corresponding to a respective V_{T} level. For example, the “11” state can be an erased state and the “01”, “10” and “00” states can each be a respective programmed state. Another type of cell is a triple level cell (TLC), which stores 3 bits per cell and defines 8 states (“111” or “L0”, “110” or “L1”, “101” or “L2”, “100” or “L3”, “011” or “L4”, “010” or “L5”, “001” or “L6”, and “000” or “L7”) each corresponding to a respective V_{T} level. For example, the “111” state can be an erased state and each of the other states can be a respective programmed state. Another type of a cell is a quad-level cell (QLC), which stores 4 bits per cell and defines 16 states L0-L15, where L0 corresponds to “1111” and L15 corresponds to “0000”. Another type of cell is a penta-level cell (PLC), which stores 5 bits per cell and defines 32 states. Other types of cells are also contemplated. Thus, an n-level cell can use 2ⁿ levels of charge to store n bits. A memory device can include one or more arrays of memory cells such as SLCs, MLCs, TLCs, QLCs, PLCs, etc. or any combination of such. For example, a memory device can include an SLC portion, and an MLC portion, a TLC portion, a QLC portion, or a PLC portion of cells.

In order to improve endurance of a memory device, the data to be written to the memory device may be modulated to achieve a desired distribution of the charge levels in the memory cells addressable by a given wordline and, in some implementations, also in the memory cells addressable by neighboring wordlines of the given wordline. For example, a random data pattern encoded by a gray code would result in uniform distribution of the memory cell charge levels (such that the number of memory cells at an arbitrary chosen charge level being roughly equal to the number of memory cells at any other charge level).

The modulated data may be encoded prior to being stored on a memory device, and thus would need to be decoded when later retrieved from the memory sub-system. For example, a sequence of symbols (e.g., representing one or more bits of binary information), may be transformed by an encoder to generate a codeword, which may then be stored on a memory device. In some cases, the sensed data read back from the memory device may differ from the original encoded data, e.g., on account of errors that may have occurred during storage and/or retrieval of the encoded data to/from the memory device.

In some implementations, the data may be encoded using an error correcting code (ECC), which produces encoded data that includes redundant information allowing the original data to be recovered even if some errors have been introduced during the data storage and/or retrieval, and thus, the transformation employed by the encoder may be chosen such that the errors (e.g., bit flips that may occur when storing and/or retrieving the codeword) may be detected and corrected when the codeword is later retrieved from the memory device thereof.

Data encoded using an error correcting code may be decoded using different techniques, which may vary in terms of the input they take and the error correction capabilities they provide. Hard-decision decoding techniques, for example, may rely on a “hard” input value of a received codeword (e.g., a singular determination as to whether each bit-value of a codeword is ‘0’ or ‘1’). A memory sub-system, for example, in retrieving a stored codeword from a memory device, may perform a read operation that makes a hard decision as to the value of each bit of the codeword (i.e., as being either ‘0’ or ‘1’) and returns a series of “hard bits.”

In some implementations, upon failing to successfully decode the sensed data based on the hard bits, the memory sub-system may perform read error handling operations in an attempt to recover the data. In some implementations, the read error handling operations may include soft-decision decoding (e.g., 1 hard bits (H)/2 soft bits (S) (1H2S)). The soft-decision decoding may consider “soft” input information (alongside a hard input value) indicating the reliability of a hard value determination (e.g., a confidence level or likelihood that a particular bit-value is in fact ‘0’ or ‘1’). Thus, a memory sub-system, in retrieving a stored codeword, may perform a read operation that not only returns a hard value as a series of hard bits, but also a series of one or more “soft bits” for each hard bit, which may indicate a reliability of a particular hard bit determination. A read operation may measure the threshold voltage of a target memory cell of a set of memory cells. By comparing the measured threshold voltage value to the estimated threshold voltage distributions associated with the set of memory cells, the read operation may return a predefined number of “soft bits” of information for each “hard” bit. Soft-decision decoding may be described in terms of the number of hard bits (H) and soft bits (S) that are provided as input to the decoder (e.g., 1H2S, 1H3S, etc.).

The combination of the hard bit and the soft bits may be converted into a likelihood value (“confidence”), which reflects the probability that the memory cell will be decoded as a specific binary value (e.g., “1”). In other words, the combination of the hard bit and one or more corresponding soft bits may be translated into a likelihood value that reflects the probability of the memory cell to be decoded as a particular binary value (e.g., “1”). In some implementations, converting the combination of the hard bit and the soft bits into a corresponding likelihood value may be performed using a look-up table, which may map various possible combinations of the hard bit and soft bits into corresponding likelihood values. The look-up table may be pre-computed by the manufacturer of the memory sub-system and stored in the metadata area of a memory device.

In an illustrative example, a memory sub-system may perform a read operation that returns a voltage value for a particular memory cell. The voltage value may be associated with one hard bit value and one or more soft bit values. For example, the memory sub-system may perform a read operation that returns three soft bits of information for each hard bit (i.e., 1H3S), with ‘000’ indicating the highest level of reliability and ‘111’ indicating the lowest level of reliability in the hard bit determination. A likelihood value can be obtained through the look-up table that maps various possible combinations of the hard bit and soft bits into corresponding likelihood values, and the likelihood value is input into the decoder for decoding the sensed data. Although the soft bits of information provide some reliability information, improvements can be made to provide additional reliability information based on hard bits of information.

Aspects of the present disclosure address the above and other deficiencies by having a memory sub-system that uses the last strobe data obtained in hard-decision decoding to identify one or more faulty bit(s) of sensed data and obtains a likelihood value (i.e., confidence) corresponding to each faulty bit (e.g., through a look up table), where the likelihood value can be used in soft-decision decoding to replace the corresponding originally-used likelihood value to improve the reliability. The updated likelihood value reflects a consideration on the position of error by using the information of the faulty bits. The rationale is that while soft bits indicate a likelihood value that a particular bit-value is in fact ‘0’ or ‘1’ (e.g., by a Euclidean distance of the measured voltage to the reference voltage levels), the likelihood value obtained based on historical and statistical data (e.g., through a look up table) may further limit this confidence or likelihood value (e.g., the Euclidean distance falls in a distance range (e.g., in a left or right side) of the reference voltage levels) of the identified bit.

In particular, the controller of a memory sub-system performs a read operation using a sequence of strobes to obtain the sensed data which is a series of “hard bits.” A strobe refers to applying a particular read level voltage (e.g., a sum of the read level offset voltage and the base read level). The controller may store the sensed data in a page buffer (e.g., a secondary data cache (SDC) of the page buffer). The controller may at the same time store, in the page buffer (e.g., a sense amplifier (SA) or a primary data cache (PDC) of the page buffer), data sensed by the strobe performed most recently among the sequence of strobes (“last strobe data”). Responsive to determining that the decoder fails to successfully decode the sensed data based on the hard bits (e.g., by calculating a checksum or cyclic redundancy check (CRC) value over the sensed data), the controller can identify, based on the sensed data and the last strobe data, one or more logical state(s). For example, the controller may perform an arithmetical operation (e.g., the exclusive disjunction (XOR) operation) on the sensed data and the last strobe data in order to identify the faulty bit(s) of the sensed data based on the result of the arithmetical operation. The controller can then obtain a likelihood value (e.g., log likelihood ratio (LLR) value) for each of the identified faulty bit(s), for example, according to a pre-configured likelihood lookup data structure. This newly-obtained likelihood value would additionally improve the reliability by replacing the originally-used likelihood value, as it is obtained based on historical and statistical data and pre-configured during manufacturing. The controller can perform, using the newly-obtained likelihood value, the soft-decision decoding the encoded host data (e.g., by a low density parity check (LDPC) decoder). In some cases, the controller can perform the soft-decision decoding with the originally-used likelihood value and, responsive to determining that the soft-decision decoding fails, replace the originally-used likelihood value with the newly-obtained likelihood value and perform the soft-decision decoding again with the newly-obtained likelihood value. In some cases, the controller can replace the originally-used likelihood value with the newly-obtained likelihood value before performing any soft-decision decoding and then perform directly the soft-decision decoding with the newly-obtained likelihood value.

Advantages of the present disclosure include, but are not limited to, improve the data reliability, reduces latency and increases the efficiency of the error handling operation, thereby improving read performance, quality of service (QoS), and reliability of the memory device. Further, no additional hardware is required, and no additional read operation is needed to obtain last strobe information.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

In some implementations, memory sub-system 110 may receive a request from the host system 120 to read host data that was previously encoded and stored in memory device 130 and/or 140. In response to the request, memory sub-system 110 may perform a read operation to read the encoded host data from memory device 130 and/or 140. The encoded host data read back from the memory device 130 and/or 140 (or sensed data) may comprise one or more sensed codewords. The sensed data may be decoded by a decoder of the memory sub-system 110 to obtain the host data encoded. In some instances, the sensed data read back from the memory device may differ from the initial encoded data that was first generated, for example, on account of errors (e.g., bit-flip errors) that may have occurred during storage and/or retrieval of the encoded data to/from the memory device. The ECC used to encode the host data may be used to recover the original host data. In particular, the ECC detects and attempts to correct any errors in the sensed data. In the event the decoder of the memory sub-system 110 is unable to correct the errors in the sensed data, the decoder of the memory sub-system 110 attempts to recover the original host data from the sensed data, for example, by performing a sequence of error handling operations (or error handling sequence).

The memory sub-system 110 includes an ECC confidence component 113 that can adjust confidence for error handling operations using strobe information in a memory device. In some embodiments, the memory sub-system controller 115 includes at least a portion of the ECC confidence component 113. In some embodiments, the ECC confidence component 113 is part of the host system 120, an application, or an operating system. In other embodiments, local media controller 135 includes at least a portion of ECC confidence component 113 and is configured to perform the functionality described herein. Further details with regards to the operations of the ECC confidence component 113 are described below.

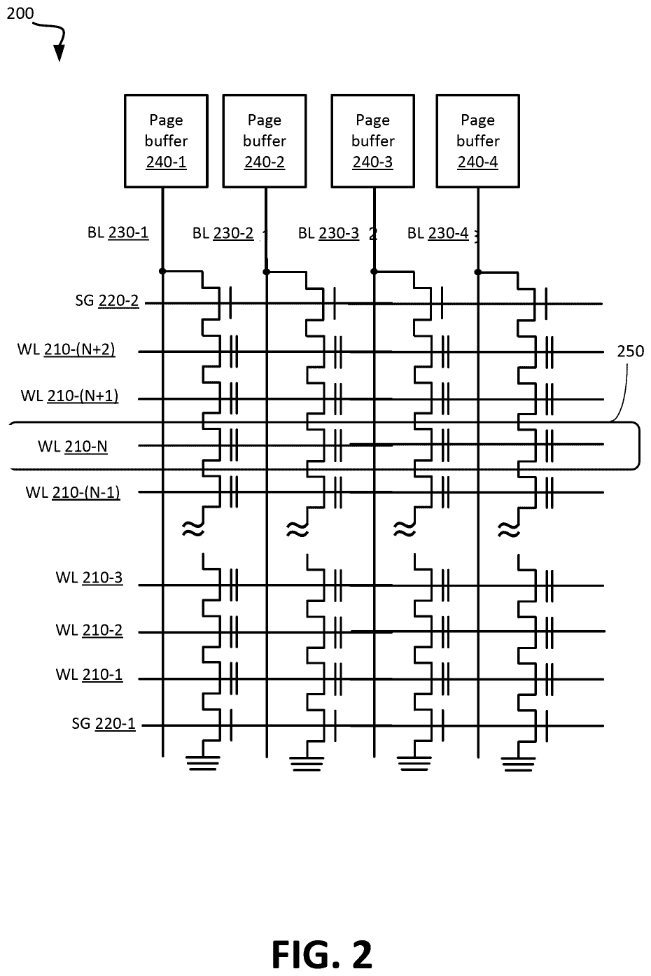

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In one embodiment, memory sub-system controller 115 includes ECC confidence component 113 configured to utilize read operations to obtain LLR values to be used in a soft-decision decoding, which is described in detail with respect to FIGS. 2-7.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 236 and outputs data to the memory sub-system controller 115 over I/O bus 236.

For example, the commands may be received over input/output (I/O) pins [7:0] of I/O bus 236 at I/O control circuitry 160 and may then be written into command register 124. The addresses may be received over input/output (I/O) pins [7:0] of I/O bus 236 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

FIG. 2 is a diagram of a portion of a memory array 200, in accordance with some embodiments. The memory array 200 can include any suitable number of wordlines (WLs). For example, as shown, the memory array 200 includes a number of wordlines WL 210-1 through WL 210-(N+2). Each of the WLs 210-1 through 210-(N+2) is connected to a respective set of cells. Each of the WLs 210-1 through 210-(N+2) is adjacent to at least one WL. For example, WL 210-(N+1) and WL 210-(N−1) are each adjacent wordlines with respect to WL 210-N. The memory array 200 further includes select gate (SG) 220-1 and SG 220-2 In some embodiments, SG 220-1 is a source-side SG (SGS) and SG 220-2 is a drain-side SG (SGD).

The memory array 200 further includes a number of bitlines (BLs) including BL 230-1 through 230-4 and a number of page buffers including page buffers 240-1 through 240-4. Each of the page buffers is connected to a respective one of the bitlines. Although only 4 bitlines 230-1 through 210-3 and page buffers 240-1 through 240-4 are shown, the memory array 200 can include any suitable number of bitlines and page buffers. A page buffer is a circuit block comprising a number of memory elements and additional circuitry. A page buffer stores data temporarily (e.g., buffered) while data is being either programmed to or read from memory cells of the memory array 200. Each page buffer can be coupled to a bitline and used to latch data sensed from the memory array during a read operation, and to store data to be programmed into the memory array (e.g., the page cache stores data read from the memory array, or host data to be written to the memory array). The page buffer includes static memory elements (e.g., latches), such as a primary data cache (PDC) and a secondary data cache (SDC). The PDC holds data that is used to keep the bit line at a voltage level sufficient to shift a threshold voltage of a memory cell during programming, or to sense the data from a bit line during a read operation. The SDC is a memory element accessible to the host system and is used as a data read/write buffer. The PDC and SDC are independent from one another. The page cache can further include a sense amplifier (SA) to read data from memory cells and dynamic memory elements. In some embodiments, sense amplifier can include various transistors or amplifiers to detect and amplify a difference in signals obtained based on reading a memory cell, which can be referred to as latching. Data obtained by the strobe reads can be stored in the sense amplifier of the memory array. For example, the page buffer 240-1 is a buffer used to temporarily store data being read from or written to the memory array 104 of the memory device 130, and can include a cache register 172 and one or more data registers 170.

In some embodiments, the memory sub-system controller 115 can direct program operations that program data stored in the page buffer 240 into a set of sub-blocks of an array of memory cells 104 of the memory device 130. For example, the memory sub-system controller 115 can cause hardware initialization of the set of sub-blocks that are to be programmed within the array. The memory sub-system controller 115 can further cause a sub-block of the set of sub-blocks to be preconditioned for a program operation. In these embodiments, the memory sub-system controller 115 further causes multiple pages of data to be programmed to respective ones of the set of sub-blocks. The memory sub-system controller 115 can further cause a program verify to be performed on memory cells of the set of sub-blocks after programming the multiple pages of data. For example, for a program operation, the memory sub-system controller 115 writes the data to the cache register 442, which is then passed to one of the data registers 172, and finally programmed to the memory array 104. If the program operation includes multiple pages (e.g., UP, XP, and TP), each page can have a dedicated data register to hold the corresponding page data.

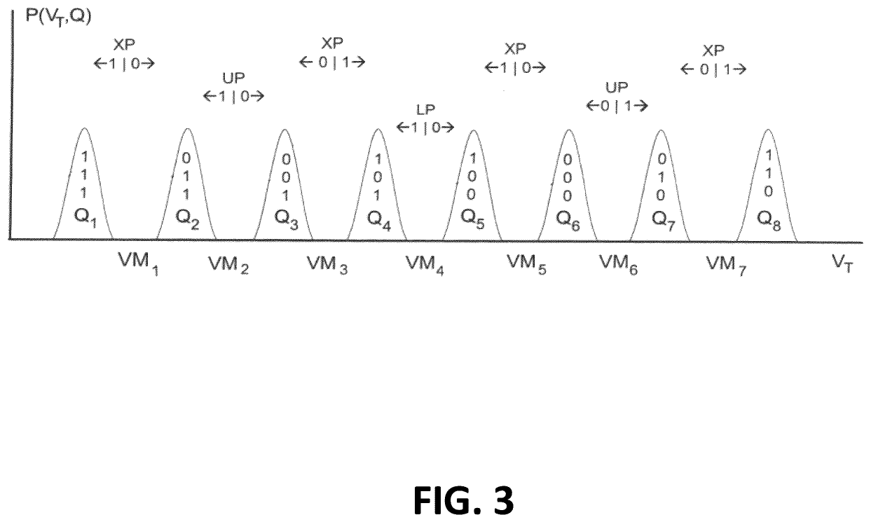

For a read operation, the data is read from the memory array 105 into one of data register 170 (e.g., PDC), and then into the cache register 172 (e.g., SDC). The memory sub-system controller 115 can then read out the data from the cache register 172. In this illustrative example, a set of target cells 250 is selected to be read. The set of target cells 250 includes a number of cells of the target wordline WL 210-N. Each target cell of the set of target cells 250 is adjacent to a pair of adjacent cells. More specifically, the pair of adjacent cells for a particular target cell includes the cell connected to WL 210-(N+1) that is directly above the target cell, and the cell connected to WL 210-(N−1) that is directly below the target cell. That is, a target cell of the set of target cells 250 is connected to a same one of the bitlines as its respective pair of adjacent cells. The memory sub-system controller 115 (e.g., ECC confidence component 113 of FIG. 1) may receive a request to initiate a read operation with respect to the set of target cells 250 via a local media controller (e.g., local media controller 135 of FIG. 1). The memory sub-system controller 115 (e.g., ECC confidence component 113 of FIG. 1) may adjust confidence for read error handling using strobe information and perform the ECC decoding operation via the local media controller. Further details regarding adjusting confidence for read error handling using strobe information are described above with reference to FIGS. 1A-1B and will be described in further detail below with reference to FIGS. 3-7.

FIG. 3 illustrates schematically a distribution of threshold control gate voltages for a memory cell capable of storing three bits of data by programming the memory cell into at least eight charge states that differ by the amount of charge on the cell's charge storage node. FIG. 3 shows distributions of threshold voltages P(V_{T}, Qₖ) for 2^{N}=8 different charge states of a tri-level cell (TLC) separated with 2³−1=7 valley margins VMₖ. Accordingly, a memory cell programmed into a charge state k-th (i.e., having the charge Qₖ deposited on its charge storage node) can be storing a particular combination of N bits (e.g., 0110, for N=4). This charge state Qₖ can be determined during a readout operation by detecting that a control gate voltage V_{CG} within the valley margin VMₖ is sufficient to open the cell to the source-drain current whereas a control gate voltage within the preceding valley margin VMₖ₋₁ is not.

For example, a TLC can be capable of being in one of eight charging states Qₖ (where the first state is an uncharged state Q₁=0) whose threshold voltage distributions are separated by valley margins VMₖ that can be used to read out the data stored in the memory cells. For example, if it is determined during a read operation that a read threshold voltage falls within a particular valley margin of 2^{N}−1 valley margins, it can then be determined that the memory cell is in a particular charge state out of 2^{N} possible charge states. By identifying the right valley margin of the cell, it can be determined what values all of its N bits have. The identifiers of valley margins (such as their coordinates, e.g., location of centers and widths) can be stored in a read level threshold register of the memory controller 215.

As noted herein above, the memory controller 215 can program a state of the memory cell and then can read this state by comparing a read threshold voltage V_{T} of the memory cell against one or more read level thresholds. The read operation can be performed after a memory cell is placed in one of its charged states Qₖ by a previous write operation, which can include one or more programming passes. Each programming pass would apply appropriate programming voltages to a given wordline M in order place appropriate charges on the charge storage nodes of the memory cells that are connected to the wordline M.

In some embodiments, the memory controller can implement a two pass programming algorithm, which involves programming the lower page (LP) bits of the memory cells by the first programming pass, followed by programming the upper page (UP) bits and the extra page (XP) bits of the memory cells by the second programming pass. This algorithm can be referred to as 2-8 programming algorithm, to reflect the number of memory cell states programmed by each pass. The first programming pass forms, for each memory cell, two states, L0 and LP. The second programming pass forms, for each memory cell, four states corresponding to each of L0 and LP states. The newly formed states are referred to as L0, L1, L2, and L3 for the original L0 state, and L4, L5, L6, and L7 for the original LP state. Thus, each memory cell stores eight states that are programmable by two sequential programming passes. Notably, the UP and XP data is still stored by the host during the second programming pass.

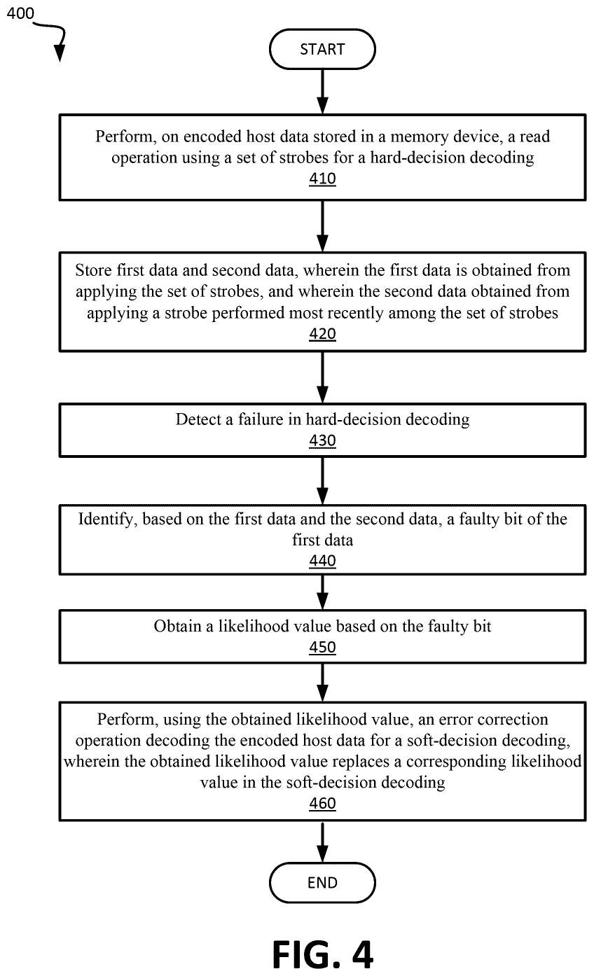

FIG. 4 is a flow diagram of an example method 400 of adjusting confidence for read error handling using strobe information in a memory device, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the ECC confidence component 113 of FIGS. 1A and 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

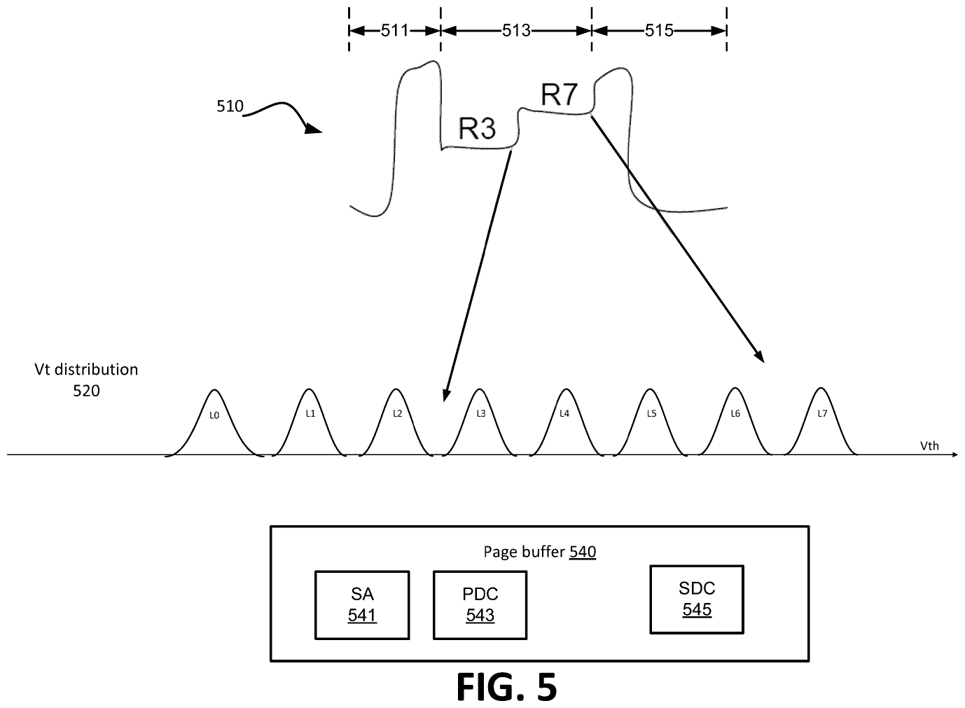

At operation 410, the processing device may perform, on encoded host data stored in the memory device (e.g., memory cells 104 in the memory device 130), a read operation for a hard-decision decoding using a sequence of strobes (e.g., using the control gate voltage 410 including a sequence of strobes R3 and R7 as shown in FIG. 5) to obtain the sensed data (“first data”). The processing device may obtain first data from applying the sequence of strobes. The processing device may obtain second data from applying a last strobe of the sequence of strobes, the last strobe being performed most recently among the sequence of strobe. Using FIG. 5 as an example, the strobe R3 is first applied and the result of applying strobe R3 is a first bit sequence of 1s and 0s and stored in the sense amplifier of the page buffer and then transferred to the secondary data cache of the page buffer. The strobe R7 is then applied and the result of applying strobe R7 is a second bit sequence of 1s and 0s. The second bit sequence is stored as the second data described below in the sense amplifier of the page buffer, which now replaces the first bit sequence. The second bit sequence is applied to an inverter and the result of inverting the second bit sequence is then transferred to the secondary data cache of the page buffer. In the secondary data cache, the stored first sequence and the stored inverted second sequence are input to an arithmetical operation (e.g., the exclusive disjunction (XOR) operation) and the output of the arithmetical operation is stored as the first data.

At operation 420, the processing device may store the first data in a secondary data cache of the page buffer. In some implementations, the processing device may store the first data in a sense amplifier of the page buffer first and then transfer the first data to the secondary data cache of the page buffer so that the sense amplifier can be released for storage of the following data (e.g., last strobe data). As shown in FIG. 5, the processing device may store the first data in the SA 541 first and then send to SDC 545 for storage. In some implementations, the set of strobes is specific to a page type (e.g., strobes R3 and R7 are specific to the extra page (XP) bits programming as shown in FIG. 5), and the set of strobes are predetermined to correspond to particular logical levels (e.g., strobes R3 and R7 correspond to logical states L3 and L7, respectively, as shown in FIG. 5). In some implementations, the set of strobes may be determined by the grey code of which adjacent numbers have a single digit different by one. Because each page type (e.g., lower page (LP), upper page (UP), extra page (XP), etc.) corresponds to different digit of the grey code, different sets of strobes may be preset to respective page type. For example, as shown in FIG. 5. strobes R3 and R7 are specific to the extra page (XP) bits programming where the single digit of the gray code may be 00011110 for the eight logical states, and the change from 0 to 1 corresponds to strobe R3 and the change from 1 to 0 corresponds to strobe R7.

At operation 420, the processing device may store second data obtained from applying a strobe performed most recently among the sequence of strobes (“last strobe”) (e.g., using the control gate voltage 510 of strobe R7 as shown in FIG. 5). The processing device may store the second data in a sense amplifier or a primary data cache of a page buffer. As shown in FIG. 5, the processing device may store the second data in the SA 541 or PDC 543.

At operation 430, the processing device may determine that hard-decision decoding fails to decode the encoded host data by detecting at least one error in the first data. In some implementations, the processing device may calculate a checksum or cyclic redundancy check (CRC) value over the first data, and this value serves as a preliminary verification mechanism to detect any errors in the first data.

At operation 440, responsive to determining that the hard-decision decoding fails, the processing device may identify one or more faulty bits of the first data based on the first data and the second data, In some implementations, the processing device may identify the faulty bit(s) by performing an arithmetical operation (e.g., XOR operation) on the first data and the second data. In some implementations, to identify the faulty bit(s), the processing device may determine whether at least one bit of the result of the XOR operation has a bit value of ‘1’ indicating a difference between a bit of the sensed data and a corresponding bit of the last strobe data. The faulty bit(s) are identified from the result of the XOR operation by identifying a position of each bit of the result of the XOR having a bit value of ‘1.’ For example, the first data may be 11101110 and the second data may be 11111110, and the result of the XOR operation on the first data and the second data may be 00010000, and the processing device may identify the fourth faulty bit L3 having a bit value of ‘1’ and thus identify the faulty bit L3.

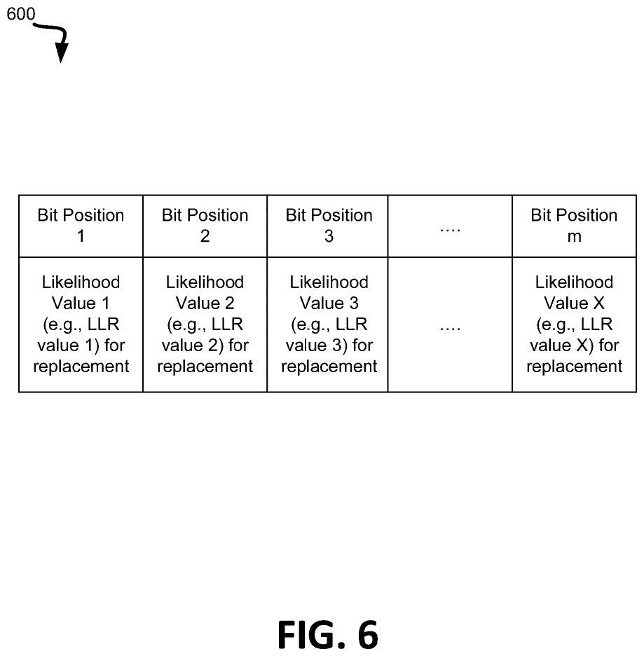

At operation 450, the processing device may obtain, based on each of the identified faulty bit(s), a respective likelihood value reflecting a probability of the bit be decoded as a specific binary value. The processing device may obtain the likelihood value for the corresponding faulty bit according to a likelihood lookup data structure. An example of the likelihood lookup data structure 600 is shown in FIG. 6. In the example illustrated above, the processing device may identify the faulty bit L3 at operation 440 and may obtain a likelihood value for faulty bit L3 according to the likelihood lookup data structure 600 at operation 450.

At operation 460, the processing device may perform, using the obtained likelihood value, an error correction operation decoding the encoded host data for the soft-decision decoding. The way to perform the soft-decision decoding using the obtained likelihood value may vary. In some implementations, the processing device may first perform the soft-decision decoding (using the original likelihood value) on the encoded host data, receive a failure notification regarding the soft-decision decoding (e.g., identify that the soft-decision decoding fails to decode the encoded host data), and perform another error correction code decoding on the encoded host data by applying the obtained likelihood value to replace a corresponding originally-assigned likelihood value used in the soft-decision decoding. In some implementations, the processing device may apply the assigned likelihood value to replace a corresponding originally-assigned likelihood value used in the soft-decision decoding and then perform, using the obtained likelihood value, the soft-decision decoding on the encoded host data. The details of the operations 450 and 460 are described below.

In some implementations, the host data may be encoded using an error correcting code (ECC), which produces encoded data that includes redundant information allowing the original data to be recovered even if some errors have been introduced during the data storage and/or retrieval. One class of ECCs that may be used are linear codes, which may be characterized by a set of linearly independent relationships. For example, a linear code having codewords of length N, that may carry K information symbols and (N−K) (or M) parity-check symbols, in general, may be characterized by (N−K) linear relationships. Linear codes may be defined by a parity-check matrix, which may describe the linear relationships that elements of a valid codeword must satisfy. Each row of a parity-check matrix, for example, may describe a separate linear relationship that a valid codeword must satisfy (e.g., requiring the weighted sum of specific elements of the codeword to equal zero), with the value in each column indicating a weight that a particular element is given in the relationship. For instance, each row of a parity-check matrix that defines a binary linear code may require the modulo-2 sum of specific bits of a codeword, which may be given a column weight of ‘1’ (and all other bits ‘0’), to be equal to zero.

In some implementations, the error correction operation may use low density parity check (LDPC) codes, which are a family of linear codes having sparsely populated parity-check matrices (e.g., having a low density of non-zero symbols). A binary LDPC code having codewords of length N, comprising K bits of information and M parity-check bits, may be defined by a parity-check matrix of size M×N. Similarly, a non-binary LDPC code, in which each symbol of the non-binary alphabet represents s bits, may be defined by a parity-check matrix of size sM×sN. A parity-check matrix having M rows and N columns may define an LDPC code having codewords of length N that may carry K information bits and M parity bits. Each row of the parity-check matrix may describe a linear relationship that a valid codeword of the LDPC code must satisfy. For example, a row of the parity-check matrix may require a valid codeword to satisfy the relationship: bit-2⊕bit-6⊕bit-7⊕ . . . ⊕bit-N−4-=0.

In some implementations, the likelihood value may be represented by the log likelihood ratio (LLR):

$$L L R ( bit i ) = log ( \frac{P ( bit i = 0 \vert read info}{P ( bit i = 1 \vert read info} ) ,$$

where i is the identifier of the bit (the memory cell for SLC), read info is the information read from the memory device (i.e., the combination of the hard bit and its corresponding soft bits), P(bit i=0|read info) is the probability of bit i be decoded as 0 based on the information read from the memory device (i.e., the combination of the hard bit and its corresponding soft bits), and P(bit i=1|read info) is the probability of bit i be decoded as 1 based on the information read from the memory device (i.e., the combination of the hard bit and its corresponding soft bits). In some implementations, converting the combination of the hard bit and the soft bits into a corresponding LLR value may be performed using a look-up table, which may map various possible combinations of the hard bit and soft bits into corresponding LLR values. As such, a decoder of soft-decision decoding can take the LLR values as input and output the decoded data.

As described above, in view of specific faulty bit(s) that is identified by using the last strobe information, a LLR value is obtained from a likelihood lookup data structure (e.g., an LLR lookup table 500 as shown in FIG. 5) according to the identified faulty bit. The likelihood lookup data structure stores for each bit position (i.e., read voltage level) a corresponding LLR value. The likelihood lookup data structure (e.g., an LLR lookup table 500) may be pre-computed by the manufacturer of the memory sub-system and stored in the metadata area of a memory device. The obtained LLR value is used to replace the LLR value that is originally assigned to be used in the soft-decision decoding. Thus, the soft-decision decoding may be performed by using the newly assigned LLR value(s) each reflecting the obtained LLR value corresponding to the identified faulty bit and the originally assigned LLR value(s) for the remaining bits (i.e., the bits that have not been identified). For example, the memory sub-system may provide the LLR values to an LDPC decoder, which may attempt to decode the sensed data using the updated LLR values.

FIG. 5 illustrates an example of adjusting confidence in ECC decoding for read error handling using strobe information in accordance with some embodiments of the present disclosure. The control gate voltage 510 applied to memory cells during a read operation can include a prologue phase 511 during which a controller activates voltage pumps (e.g., causes voltage pumps to be turned on) and loads information for the read operation, a strobe phase 513 in which a number of strobes (e.g., strobe R3 and strobe R7) are performed, and an epilogue phase 515 during which the controller causes the cells to discharge, deactivates the voltage pumps (e.g., causes the voltage pumps to be turned off) and causes the memory device to return to an idle or standby state (e.g., depending on the state of the CE# signal). A strobe refers to applying a particular read level voltage (e.g., a sum of the read level offset voltage and the base read level). In the example of FIG. 5, strobe R3 and strobe R7 are performed during the strobe phase, where strobe R3 refers to a read level offset voltage falling in the voltage valley between L2 and L3 in the Vt distribution 520, and strobe R7 refers to a read level offset voltage falling in the voltage valley between L6 and L7 in the Vt distribution 520. For each cell, the processing logic can perform a predetermined set of strobes. As describe above, in FIG. 5, for a XP page type programming, the set of strobes may be predetermined to include strobes R3 and R7. In the example of FIG. 3, for a XP page type programming, the set of strobes may be predetermined to include strobes R1, R3, R5, and R7; for a UP page type programming, the set of strobes may be predetermined to include strobes R2 and R6; for a LP page type programming, the set of strobes may be predetermined to include strobes R4;

For example, the ECC confidence component 113 may apply the control gate voltage 510 for performing a read operation. While applying the control gate voltage 510 through various phases, the ECC confidence component 113 may continually store the result sensed from applying the voltage in page buffer 540. Specifically, the ECC confidence component 113 may store the first result of applying R3 (e.g., a bit sequence “11100000”) in SA 541 of page buffer 540 and send the first result stored in SA 541 to SDC 545. SA 541 is used to store any data sensed and then may transfer the data to other place for storage. The ECC confidence component 113 may store the second result of applying R7 (e.g., a bit sequence “00000001”) in SA 541 of page buffer 540, that is, second result now replaces the first result and is stored in SA 541. The ECC confidence component 113 may send an invert of the second result stored in SA 541 to SDC 545, where the SDC 545 stores a combined result of the first result and an invert of the second result (e.g., a bit sequence “00011110”). In some implementations, the combined result of the first result and an invert of the second result may be derived by applying a Boolean logic operation (e.g., XOR operation) on the first result and an invert of the second result. In some implementations, the ECC confidence component 113 may keep the second result in SA 541 or send the second result in PDC 543 (as data storage). The combined result of the first result and an invert of the second result may be the sensed data described above, while the second result may be the last strobe data described above.

FIG. 6 illustrates an example of a likelihood lookup data structure (e.g., LLR lookup table) 600 that provides a LLR value (as a replacement value used in soft-decision decoding) for each bit position obtained using the last strobe information, in accordance with some embodiments of the present disclosure. In one embodiment, the likelihood lookup data structure is stored in local memory 119 of the memory sub-system 110. The likelihood lookup data structure 500 includes a plurality of entries. Each entry of the likelihood lookup data structure is identified by a bit position (e.g., corresponding to read voltage levels L0-L7 of FIG. 3 and FIG. 5). Each entry includes an LLR value associated with a respective logical state. The LLR values included in each entry for a respective bit position is pre-computed by the manufacturer of the memory sub-system. In some implementations, the likelihood lookup data structure is specific to a type of cell. For example, for a SLC cell, the likelihood lookup data structure may include two entries corresponding to two bit positions; for a MLC cell, the likelihood lookup data structure may include four entries corresponding to four bit positions; for a TLC cell, the likelihood lookup data structure may include eight entries corresponding to eight bit positions, for a QLC cell, the likelihood lookup data structure may include sixteen entries corresponding to sixteen bit positions, etc.

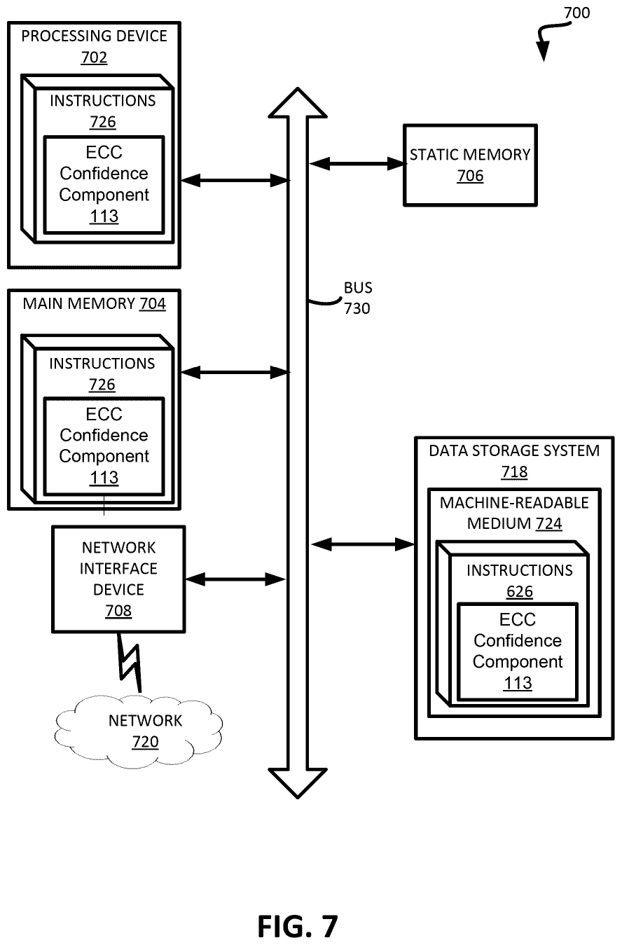

FIG. 7 illustrates an example machine of a computer system 700 within which a set of instructions, for causing the machine to perform any one or more of the methodologies discussed herein, can be executed. In some embodiments, the computer system 700 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the ECC confidence component 113 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM) or RDRAM, etc.), a static memory 706 (e.g., flash memory, static random access memory (SRAM), etc.), and a data storage system 718, which communicate with each other via a bus 730.

Processing device 702 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. The processing device 702 is configured to execute instructions 726 for performing the operations and steps discussed herein. The computer system 700 can further include a network interface device 708 to communicate over the network 720.

The data storage system 718 can include a machine-readable storage medium 724 (also known as a computer-readable medium) on which is stored one or more sets of instructions 726 or software embodying any one or more of the methodologies or functions described herein. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718, and/or main memory 704 can correspond to the memory sub-system 110 of FIG. 1A.

In one embodiment, the instructions 726 include instructions to implement functionality corresponding to an error handling component (e.g., the ECC confidence component 113 of FIG. 1A). While the machine-readable storage medium 724 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled with the memory device, to perform operations comprising:
performing, on encoded host data stored in the memory device, a read operation comprising a sequence of strobes;
obtaining first data from applying the sequence of strobes;
obtaining second data from applying a last strobe of the sequence of strobes, the last strobe being performed most recently among the sequence of strobes;
identifying, based on the first data and the second data, one or more faulty bits of the first data;
obtaining, for each faulty bit of the one or more faulty bits of the first data, a respective likelihood value reflecting a probability of the bit be decoded as a specific binary value; and
decoding, using the likelihood values, the encoded host data to produce decoded data.

2. The system of claim 1, wherein identifying, based on the first data and the second data, the one or more faulty bits of the first data is performed based on a result of performing the arithmetical operation on the first data and second data.

3. The system of claim 1, wherein decoding the encoded host data further comprises:
performing soft-decision decoding on the encoded host data;
identifying that the soft-decision decoding fails to decode the encoded host data; and
performing error correction code (ECC) decoding on the encoded host data by applying the likelihood values to replace corresponding likelihood values used in the soft-decision decoding.

4. The system of claim 1, wherein decoding the encoded host data further comprises:
applying the likelihood values to replace corresponding likelihood values used in soft-decision decoding; and
performing the soft-decision decoding with the likelihood value on the encoded host data.

5. The system of claim 1, wherein the second data is stored in a sense amplifier or a primary data cache of a page buffer, and wherein the first data is stored in a secondary data cache of the page buffer.

6. The system of claim 1, wherein obtained, for each faulty bit of the one or more faulty bits, the respective likelihood value comprises:
obtaining, from a likelihood lookup data structure, the respective likelihood value associated with each faulty bit of the one or more faulty bits, wherein the likelihood lookup data structure comprises a plurality of entries, wherein each entry of the plurality of entries is identified by a bit position and includes a corresponding likelihood value, and wherein the likelihood lookup data structure is pre-configured during manufacturing.

7. The system of claim 1, wherein the likelihood value comprises a log likelihood ratio, and wherein the error correction code comprises a low density parity check (LDPC) code.

8. A method comprising:
performing, by a processing device, on encoded host data stored in a memory device, a read operation comprising a sequence of strobes;
obtaining first data from applying the sequence of strobes;
obtaining second data from applying a last strobe of the sequence of strobes, the last strobe being performed most recently among the sequence of strobes;
identifying, based on the first data and the second data, one or more faulty bits of the first data;
obtaining, for each faulty bit of the one or more faulty bits of the first data, a respective likelihood value reflecting a probability of the bit be decoded as a specific binary value; and
decoding, using the likelihood values, the encoded host data to produce decoded data.

9. The method of claim 8, wherein identifying, based on the first data and the second data, the one or more faulty bits of the first data is performed based on a result of performing the arithmetical operation on the first data and second data.

10. The method of claim 8, wherein decoding the encoded host data further comprises:
performing soft-decision decoding on the encoded host data;
identifying that the soft-decision decoding fails to decode the encoded host data; and
performing error correction code (ECC) decoding on the encoded host data by applying the likelihood values to replace corresponding likelihood values used in the soft-decision decoding.

11. The method of claim 8, wherein decoding the encoded host data further comprises:
applying the likelihood values to replace corresponding likelihood values used in soft-decision decoding; and
performing the soft-decision decoding with the likelihood value on the encoded host data.

12. The method of claim 8, wherein the second data is stored in a sense amplifier or a primary data cache of a page buffer, and wherein the first data is stored in a secondary data cache of the page buffer.

13. The method of claim 8, wherein obtained, for each faulty bit of the one or more faulty bits, the respective likelihood value comprises:
obtaining, from a likelihood lookup data structure, the respective likelihood value associated with each faulty bit of the one or more faulty bits, wherein the likelihood lookup data structure comprises a plurality of entries, wherein each entry of the plurality of entries is identified by a bit position and includes a corresponding likelihood value, and wherein the likelihood lookup data structure is pre-configured during manufacturing.

14. The method of claim 8, wherein the likelihood value comprises a log likelihood ratio, and wherein the error correction code comprises a low density parity check (LDPC) code.

15. A non-transitory computer-readable storage medium comprising instructions that, when executed by a processing device, cause the processing device to perform operations comprising:
performing, on encoded host data stored in a memory device, a read operation comprising a sequence of strobes;
obtaining first data from applying the sequence of strobes;
obtaining second data from applying a last strobe of the sequence of strobes, the last strobe being performed most recently among the sequence of strobes;
identifying, based on the first data and the second data, one or more faulty bits of the first data;
obtaining, for each faulty bit of the one or more faulty bits of the first data, a respective likelihood value reflecting a probability of the bit be decoded as a specific binary value; and
decoding, using the likelihood values, the encoded host data to produce decoded data.

16. The non-transitory computer-readable storage medium of claim 15, wherein identifying, based on the first data and the second data, the one or more faulty bits of the first data is performed based on a result of performing the arithmetical operation on the first data and second data.

17. The non-transitory computer-readable storage medium of claim 15, wherein decoding the encoded host data further comprises:
performing soft-decision decoding on the encoded host data;
identifying that the soft-decision decoding fails to decode the encoded host data; and
performing error correction code (ECC) decoding on the encoded host data by applying the likelihood values to replace corresponding likelihood values used in the soft-decision decoding.

18. The non-transitory computer-readable storage medium of claim 15, wherein decoding the encoded host data further comprises:
applying the likelihood values to replace corresponding likelihood values used in soft-decision decoding; and
performing the soft-decision decoding with the likelihood value on the encoded host data.

19. The non-transitory computer-readable storage medium of claim 15, wherein the second data is stored in a sense amplifier or a primary data cache of a page buffer, and wherein the first data is stored in a secondary data cache of the page buffer.

20. The non-transitory computer-readable storage medium of claim 15, wherein obtained, for each faulty bit of the one or more faulty bits, the respective likelihood value comprises:
obtaining, from a likelihood lookup data structure, the respective likelihood value associated with each faulty bit of the one or more faulty bits, wherein the likelihood lookup data structure comprises a plurality of entries, wherein each entry of the plurality of entries is identified by a bit position and includes a corresponding likelihood value, and wherein the likelihood lookup data structure is pre-configured during manufacturing.
